(19) United States
(12) Patent Application Publication
(10) Pub. No.: US 2026/0119385 A1
(43) Pub. Date: Apr. 30, 2026

(54) DISAGGREGATED MEMORY STRUCTURES ON A DIRECTLY MODULATED PHOTONIC WAFER-SCALE INTERPOSER

(71) Applicant: Volantis Semiconductor, Inc., Portland, OR (US)

(72) Inventors: Tapabrata Ghosh, San Francisco, CA (US); Roy Edward Meade, II, Bastrop, TX (US)

(73) Assignee: Volantis Semiconductor, Inc., Portland, OR (US)

(21) Appl. No.: 19/243,462

(22) Filed: Jun. 19, 2025

Related U.S. Application Data
(63) Continuation-in-part of application No. 19/235,870, filed on Jun. 12, 2025.
Application No. 19/235,870 is a continuation-in-part of application No. 19/230,233, filed on Jun. 6, 2025.
Application No. 19/230,233 is a continuation-in-part of application No. 19/223,614, filed on May 30, 2025.
Application No. 19/223,614 is a continuation-in-part of application No. 19/222,606, filed on May 29, 2025.
Application No. 19/222,606 is a continuation-in-part of application No. 19/211,446, filed on May 19, 2025.
Application No. 19/211,446 is a continuation-in-part of application No. 19/210,116, filed on May 16, 2025.
Application No. 19/210,116 is a continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. G06F 12/00; G02B 6/12; G06F 11/20; G06F 13/16; H01L 25/16; H04B 10/80

(52) U.S. Cl. CPC G06F 12/00; G02B 6/12007; G06F 11/2017; G06F 13/1668; H04B 10/802; H10W 90/00

(57) ABSTRACT

Circuits, such as chiplets and memory devices, and surface-emitting light sources, such as vertical-cavity surface-emitting lasers (VCSELs), are bonded to a front side of a photonic wafer-scale interposer (PWSI). The PWSI includes waveguides for communication among the circuits, memory devices, and surface-emitting light sources. Memory devices are grouped by a memory fabric, resulting in a disaggregated memory structure. A first circuit accesses memory. The accessing is based on the disaggregated memory structure. The accessing can include sending electrical data by the first circuit to a first surface-emitting light source. A degree of freedom (DoF) of a light beam emitted by the first surface-emitting light source can be modulated. The emitted light beam can comprise a degree of freedom modulated beam (DFMB) that is based on the sent electrical data. The memory fabric can allocate memory based on memory needs of the first circuit.

### RELATED APPLICATIONS

This application is a continuation-in-part of U.S. patent application “Optical Links With Degree Of Freedom VCSEL Modulation On A Photonic Wafer-Scale Interposer” Ser. No. 19/235,870, filed Jun. 12, 2025.

The U.S. patent application “Optical Links With Degree Of Freedom VCSEL Modulation On A Photonic Wafer-Scale Interposer” Ser. No. 19/235,870, filed Jun. 12, 2025, is also a continuation-in-part of U.S. patent application “Optical Link With VCSEL Wavelength Modulation”Ser. No. 19/230,233, filed Jun. 6, 2025.

The U.S. patent application “Optical Link With VCSEL Wavelength Modulation” Ser. No. 19/230,233, filed Jun. 6, 2025, is also a continuation-in-part of U.S. patent application “Optical Link With Modulation Of VCSEL Modes”Ser. No. 19/223,614, filed May 30, 2025.

The U.S. patent application “Optical Link With Modulation Of VCSEL Modes” Ser. No. 19/223,614, filed May 30, 2025, is also a continuation-in part of U.S. patent application “Optical Link With Polarization-Switched VCSEL Modulation” Ser. No. 19/222,606, filed May 29, 2025.

The U.S. patent application “Optical Link With Polarization-Switched VCSEL Modulation” Ser. No. 19/222,606, filed May 29, 2025, is also a continuation-in-part of U.S. patent application “Hierarchical Redundancy With Parallel Optical Links” Ser. No. 19/211,446, filed May 19, 2025.

The U.S. patent application “Hierarchical Redundancy With Parallel Optical Links” Ser. No. 19/211,446, filed May 19, 2025, is also a continuation-in-part of U.S. patent application “Waveguides Based On Nanoimprint Lithography On A Photonic Wafer Scale Interposer”Ser. No. 19/210,116, filed May 16, 2025.

The U.S. patent application “Waveguides Based On Nanoimprint Lithography On A Photonic Wafer Scale Interposer” Ser. No. 19/210,116, filed May 16, 2025, is also a continuation-in-part of U.S. patent application “Photonic Wafer-Scale Interposer With Mirrors Based on Nanoimprint Lithography” Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025, is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers”Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins”Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides”Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive”Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025, is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024, is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film”Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling”Ser. No. 63/714,353, filed Oct. 31, 2024.

Each of the foregoing applications is hereby incorporated by reference in its entirety.

### FIELD OF ART

This application relates generally to transmitting data and more particularly to disaggregated memory structures on a directly modulated photonic wafer-scale interposer.

### BACKGROUND

Since the earliest days of digital computers, devices that enable loading and storing data have been required for computer operation. These “memories” have been used to store programs and data, sometimes in the same memories, such as for Princeton or von Neumann class computer architectures, and sometimes in separate memories, such as for Harvard class computer architectures. Some of these memories have been implemented as read-only memories, or ROMS. A ROM is useful for storing information such as instructions, associated with a program, that are executed repeatedly. If changes to the program are required, a new ROM is programmed with the new instructions. The instructions are loaded for execution by accessing addresses within the memory that contains the instructions. While at times the instructions are executed sequentially, the flow of instruction execution can be changed based on conditional instructions or processing exceptions. Thus, a new address can be accessed, and processing can continue. Other memories include read-write memories. The read-write memories, as with the ROMs, enable random access to stored contents, whether the contents are instructions or are data. These random access memories (RAMs) can be used to access data to be processed, and the results of the processing can be stored back to the read-write memories. Thus, programs that process data can be executed, and the results of the processing can be stored for further processing. The use of the memories for accessing programs and data significantly reduces data processing times since accesses to memory are vastly faster than obtaining instructions from external sources.

The capabilities of memory technologies have improved by many orders of magnitude over the decades. One early memory technology was the Williams tube. Invented in 1947, the tube stored binary data as an electrostatic charge. However, the tubes were relatively large and unstable. In the late 1940s and early 1950s, a competing technology based on ferrite toroidal cores was developed. The binary data was stored as magnetic polarities on the ferrite cores. This latter technology was denser, enabling greater data storage than the Williams tubes. Also, the core memories were faster, more durable, and far more stable than their tube counterparts.

With the introduction of integrated circuits in the 1960s and 1970s, semiconductor memories emerged. There are two broad classes of semiconductor memories: static memories and dynamic memories. The static memories (SRAMs) retain data as long as power is provided to the memories. The dynamic memories (DRAMS) are smaller than the comparably sized SRAMs, but “forget” unless the data within them is refreshed periodically. Memory technology has continued to progress. Solid state memory such as flash memory emerged in 1984, providing a “nonvolatile” storage option. That is, the memory retains data even when power is removed. And further technological advances enabled mass magnetic storage such magnetic hard disk drives (HDDs) to be replaced by solid-state drives (SSDs). Memory and storage technologies continue to advance and improve.

### SUMMARY

The demand for enhanced processor performance has increased exponentially during the last few decades. Computationally intensive applications such as artificial intelligence (AI), climate modeling, genome sequencing, and so on have been constrained by current technological capabilities of processors, systems-on-chip (SoCs), accelerators, servers, memory, power delivery, cooling technologies, and so on. Additional processing performance is articulated as certainly being needed. For example, today's large language model (LLM) training time can be measured in months, even while utilizing many processors and accelerators that are executing 24×7. Making further improvements will require advances in all system components. For example, memory accesses by processors, accelerators, transformers, and so on must keep pace with the ability of these processing elements to perform calculations. Otherwise, these processing elements become “starved” for data and stall. When processing elements stall, no matter how fast they are, overall performance remains unimproved. Memory access speed (latency), data transfer bandwidth, and power consumption are critical to overall system performance, whether related to today's high performance systems or to the systems that will be created in the future.

Disclosed techniques enable improved data transmission. The data transmission is based on disaggregated memory structures on a directly modulated photonic wafer-scale interposer. Circuits, such as chiplets and memory devices, and surface-emitting light sources, such as vertical-cavity surface-emitting lasers (VCSELs), are bonded to a front side of a photonic wafer-scale interposer (PWSI). The PWSI includes waveguides for communication among the circuits, memory devices, and surface-emitting light sources. Memory devices are grouped by a memory fabric, resulting in a disaggregated memory structure. A first circuit accesses memory. The accessing is based on the disaggregated memory structure. The accessing can include sending electrical data by the first circuit to a first surface-emitting light source. A degree of freedom (DoF) of a light beam emitted by the first surface-emitting light source can be modulated. The emitted light beam can comprise a degree of freedom modulated beam (DFMB) that is based on the sent electrical data. The memory fabric can allocate memory based on memory needs of the first circuit.

A method for transmitting data is disclosed comprising: bonding, to a front side of a photonic wafer-scale interposer (PWSI), a plurality of circuits, a plurality of memory devices, and a plurality of surface-emitting light sources, wherein the PWSI includes a plurality of waveguides; grouping, by a memory fabric, one or more memory devices within the plurality of memory devices, wherein the grouping results in a disaggregated memory structure; and accessing memory, by a first circuit within the plurality of circuits, wherein the accessing is based on the disaggregated memory structure.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for disaggregated memory structures on a directly modulated photonic wafer-scale interposer.

FIG. 2 is a flow diagram for delivering data to a memory device.

FIG. 3 is a cross-section of a VCSEL.

FIG. 4 is an architectural example of a disaggregated memory structure on a photonic wafer-scale interposer.

FIG. 5 is a block diagram of an optical link with VCSEL modulation.

FIG. 6 is an apparatus for disaggregated memory structures on a photonic wafer-scale interposer.

FIG. 7 is a system diagram for disaggregated memory structures on a directly modulated photonic wafer-scale interposer.

### DETAILED DESCRIPTION

Techniques for transmitting data using disaggregated memory structures on a directly modulated photonic wafer-scale interposer are disclosed. The relentless demand for increased processing performance taxes the capabilities of today's processors and other system elements such as memories and data switches. To address the increasing demand, high performance systems-on-chip (SoCs) have been designed. The SoCs can include processors such as multiprocessors, cores, memories, switching elements, and so on. These SoC's can boast transistor counts in the tens of billions. Further advancing the extent of system-level performance, accelerators, such as artificial intelligence (AI) accelerators, have been designed and developed to offload and accelerate particularly challenging calculations. In a usage example, today's large language models can depend on many such scaled-out accelerators to perform training and inferencing. As raw processing power increases, the bandwidth and the speed of memory elements become limiting factors in system performance. Thus, the increasing processing performance is driving the need for faster, higher bandwidth memory systems, leading to memory advancements such as HBM memories, where memory dies can be stacked on a single substrate.

A further avenue for boosting system performance has been to pursue memory organizations and structures that speed providing data from memory to processors. Previously, simple bus architectures such as the Peripheral Component Interconnect (PCI) bus enabled sufficient bandwidth to keep processor elements from stalling. Stalling occurs when the processor elements are starved for data because the required data did not arrive in time. But as these elements grew in their ability to process more data more efficiently, additional methods of interconnect were developed. For example, high speed serial links such as PCI Express (PCIe) enabled gigabit-per-second speeds on multiple “lanes.” As processing power has further increased, optical communications have become a low power, high bandwidth alternative to wire-based techniques for transferring data between processing elements. For example, multimode fibers enable remarkably high bandwidth short-reach optical links which can be used between server racks, switches, storage, and so on.

To address these performance bottlenecks, disaggregated memory structures on a directly modulated photonic wafer-scale interposer are disclosed. Circuits, memory devices, and surface-emitting light sources, such as vertical-cavity surface-emitting lasers (VCSELs), are bonded to a photonic wafer-scale interposer (PWSI). The PWSI includes waveguides that can be used to communicate among the chips, memories, and surface-emitting light sources. The circuits can be circuits within chips, chiplets, systems-on-chip (SoCs), wafers, etc. A memory fabric groups together one or more memory devices, resulting in a disaggregated memory structure. Unlike traditional memory structures where memories such as cache memories are tightly coupled to processors to speed memory access, the disaggregated memory structure enables groups comprising one or more memory devices to be shared among processors. A first circuit accesses memory based on the disaggregated memory structure. The memory fabric can allocate one or more memory devices to a first processor as the first processor requires data. The same one or more memory devices can be allocated to other processors when the first processor has obtained needed data, and the other processors require data. By utilizing the waveguides associated with the PWSI, sufficient memory access speed is enabled, thereby limiting or eliminating “data starvation”and commensurate stalling of the processors.

The accessing of one or more memory devices by a circuit can include sending electrical data from the first circuit to a first VCSEL. The sending can include a first LED, a first laser diode, and so on. The first VCSEL can convert electrical data from a circuit to optical data. The optical data can be conveyed as light. A degree of freedom (DoF) of a light beam emitted by the first VCSEL can be modulated, resulting in a degree of freedom modulated beam (DFMB). The DFMB is based on the electrical data that was sent. The DFMB can be coupled optically to a waveguide within the PWSI. The waveguide can be further coupled to an optical decoding element (ODE). The ODE can comprise a grating coupler, a mirror, a polarization filter, a polarization multiplexor (PMUX), and so on. The ODE can decode the DFMB into the electrical data that was sent. In the case of a PMUX, a polarized beam splitter (PBS) can separate the DFMB into at least two degree of freedom optical signals. The PBS can be within the PMUX. The separating can be based on a plane of polarization of the DFMB, a light mode, a light wavelength, etc. Each degree of freedom optical signal can be transformed by a unique photodiode. The transforming can result in at least two electrical signals. These electrical signals can be assembled into a single electrical signal. The single electrical signal can comprise the electrical data that was sent. The electrical data can be delivered to a second circuit, which can be a chiplet, an SoC, a wafer, an ASIC, a core, a core on a wafer, and so on. The second circuit can comprise a circuit within a chip, a chiplet, an SoC, a wafer, etc. Other optical media in addition to a waveguide can be used to transmit the DFMB. In a usage example, an optical medium can comprise an optical fiber.

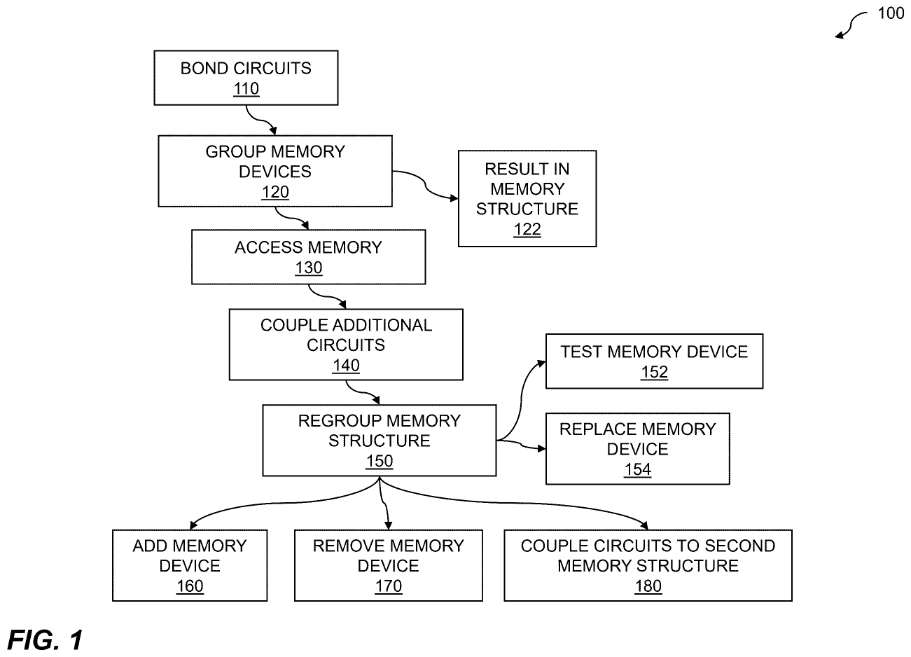

FIG. 1 is a flow diagram for disaggregated memory structures on a directly modulated photonic wafer-scale interposer. The flow 100 includes bonding 110, to a front side of a photonic wafer-scale interposer (PWSI), a plurality of circuits, a plurality of memory devices, and a plurality of surface-emitting light sources. The PWSI includes a plurality of waveguides. A circuit can comprise a chiplet; an SoC; a wafer; an ASIC; a core; a core on a wafer; a circuit within a chip, chiplet, SoC, or wafer; and so on. In embodiments, the plurality of circuits comprises a plurality of chiplets. The memory devices can include high performance memory devices such as a high bandwidth memory (HBM) chip (explained below). In embodiments, the plurality surface-emitting light sources comprise a plurality of vertical-cavity surface-emitting lasers (VCSELs). The plurality of surface-emitting light sources can include LEDs, laser diodes, etc. The surface-emitting light sources can be modulated. Thus, the PWSI can comprise a directly modulated PWSI. The bonding the circuits, the memory devices, and the surface-emitting light sources to the PWSI can be accomplished using soldering techniques, adhesives, elastomeric sheets, laser assisted bonding, and other techniques that enable coupling the circuits, the memory devices, and the surface-emitting light sources to the PWSI. The coupling the circuits, memory devices, and surface-emitting light sources enables electrical coupling to pads, wire, interconnect, and vias associated with the PWSI. The coupling further enables access to the waveguides within the PWSI.

The flow 100 includes grouping 120, by a memory fabric, one or more memory devices within the plurality of memory devices. The memory devices can include devices suitable for highspeed data access. In embodiments, at least one memory device within the one or more memory devices comprises a high bandwidth memory (HBM) chip. A HBM chip can offer high bandwidth for data transfer. The HBM can further offer low latency, thereby speeding memory access operations. In embodiments, the HBM chip includes one or more stacks of memory dies. HBM devices can be based on three-dimensional (3D) stacking of memory elements. The 3D stacking of memory elements enables denser placement of memory devices on a PWSI. The 3D stacking of memory devices further enables low latency due to shorter wiring paths between memories compared to single-stacked memory devices. HBM devices can also feature low power consumption. The grouping is accomplished by a memory fabric. A memory fabric can comprise a high-performance, low-latency interconnect architecture. The memory fabric can couple various memory resources, such as the plurality of memory devices, to compute resources, such as the plurality of circuits. The interconnect architecture can be coherent. The memory fabric can abstract a physical location of the memory devices, making it appear to the circuits, such as chiplets, that the memory is local. The memory fabric can include a controller which can direct traffic between nodes within the fabric. The memory fabric can implement distributed control of traffic without the need of a separate controller. In embodiments, the memory fabric is based on data packets. Data packets can comprise units of data transmitted across the memory fabric. Packets may contain headers, payloads, error-checking and/or correction fields, and so on. In some embodiments, the memory fabric is based on a High Bandwidth Memory interface. The High Bandwidth Memory (HBM) interface can communicate with HBM memory chips when one or more HBMs are used as memory devices on the PWSI. In other embodiments, the memory fabric is based on a Compute Express Link (CXL) interface. CXL can be a compute protocol enabling high-bandwidth, low-latency interconnect. In further embodiments, a CXL interface includes memory pooling. A memory pooling feature within a CXL can enable a flexible, disaggregated memory structure.

In the flow 100, the grouping results in a disaggregated memory structure 122. In a disaggregated memory structure, the memory devices are not tightly coupled to specific processing elements. Instead, the disaggregated memory devices can be pooled. The pooled memory devices can be shared among one or more chips within the plurality of chips. Thus, in contrast to tightly coupling memory to a processing element, as in traditional processing architectures, the processing elements can access memory devices within the disaggregated memory structure as and when memory is needed. When other processing elements require memory, the memory devices within the disaggregated memory structure can be shared with the other processing elements. Further, if a processing element requires more (or less) memory, then additional (or fewer) memory devices within the disaggregate memory structure can be assigned to the processing element. In embodiments, the disaggregated memory structure comprises one or more memory devices within the plurality of memory devices, wherein the one or more memory devices are dynamically allocated between one or more circuits within the PWSI, and wherein the one or more memory devices are independent from the one or more circuits.

The flow 100 includes accessing memory 130, by a first circuit within the plurality of circuits, wherein the accessing is based on the disaggregated memory structure. The pooled memory devices are accessible by the processing elements via highspeed interconnect. In a usage example, the disaggregated memory structure is accessible to the processing elements via waveguides within the PWSI. In a second usage example, the disaggregated memory structure can be accessible to the processing elements via one or more optical fibers.

The flow 100 includes coupling, by the memory fabric, one or more additional circuits 140 within the plurality of circuits to the disaggregated memory structure. The additional one or more circuits can include circuits that are substantially similar to the first circuit or substantially different from the first circuit. The additional one or more additional circuits can include chiplets, cores, SOCs, ASICs, etc. The additional one or more circuits can include AI accelerators, switching circuits, etc. The additional circuits can be coupled to the disaggregated memory structure based on storage needs of circuits that access the disaggregated memory structure. The additional circuits can be coupled based on memory device availability. The coupling can occur statically (e.g., at start-up) or dynamically (e.g., during operation).

The flow 100 further includes regrouping 150, by the memory fabric, the disaggregated memory structure. Discussed above, the regrouping can be based on a need for more storage (e.g., increase number of memory devices), less storage (e.g., decrease number of memory devices), availability of memory devices, and so on. The regrouping can be based on status of a memory device, where the status can include functional, failing, failed, and the like. An available memory device can include an unused memory device. In embodiments, a memory device within the one or more memory devices that were grouped comprises a spare memory device. The flow 100 further includes testing memory devices 152. Embodiments include testing each memory device within the disaggregated memory structure. The testing of each memory device can be accomplished at system startup, when a memory device is idle, during operation, and so on. In a usage example, the testing can include functional testing of the memory device. The testing can be based on a built-in self-test (BIST). The flow 100 further includes replacing a failing memory device 154 within the one or more memory devices, wherein the replacing is based on the spare memory device. The replacing can be accomplished by electrically switching out the failing device and electrically switching in a spare memory device. The replacing can be accomplished by hot swapping. Embodiments include replacing a failing memory device within the one or more memory devices, wherein the replacing is based on the spare memory device.

In the flow 100, the regrouping comprises adding 160 a memory device. In embodiments, the regrouping comprises adding a memory device, within the plurality of memory devices, to the disaggregated memory structure. The memory device to be added can be adjacent to a group of memory devices, accessible to the group, etc. The added device can include a spare device. In the flow 100, the regrouping comprises removing 170 a memory device. In embodiments, the regrouping comprises removing a memory device within the one or more memory devices that were grouped, to the disaggregated memory structure. A memory device can be removed from a group by disabling (e.g., deselecting) the memory device, by grouping the device with another disaggregated memory structure, etc.

In embodiments, the grouping includes another one or more memory devices within the plurality of memory devices, wherein the grouping results in a second disaggregated memory structure. Any number of disaggregated memory structures can be created on the PWSI. A maximum number of disaggregated memory structures can be based on the number of memory devices on the PWSI, a number of dies within the memory devices on the PWSI, and so on. Any memory device can be allocated to any disaggregated memory structure at any time by the memory fabric. A second disaggregated memory structure can be formed to provide memory access to additional circuits within the plurality of circuits. The flow 100 further includes coupling circuits to the second memory structure 180. Embodiments include coupling, by the memory fabric, one or more other circuits to the second disaggregated memory structure. In embodiments, the accessing includes the second disaggregated memory structure. By coupling one or more circuits to the second disaggregated memory structure, circuits accessing the first disaggregated memory structure and circuits accessing the second disaggregated memory structure can operate in parallel.

Various steps in the flow 100 may be changed in order, repeated, omitted, or the like without departing from the disclosed concepts. Various embodiments of the flow 100, or portions thereof, can be included in an apparatus for transmitting data or system that is configured to transmit data.

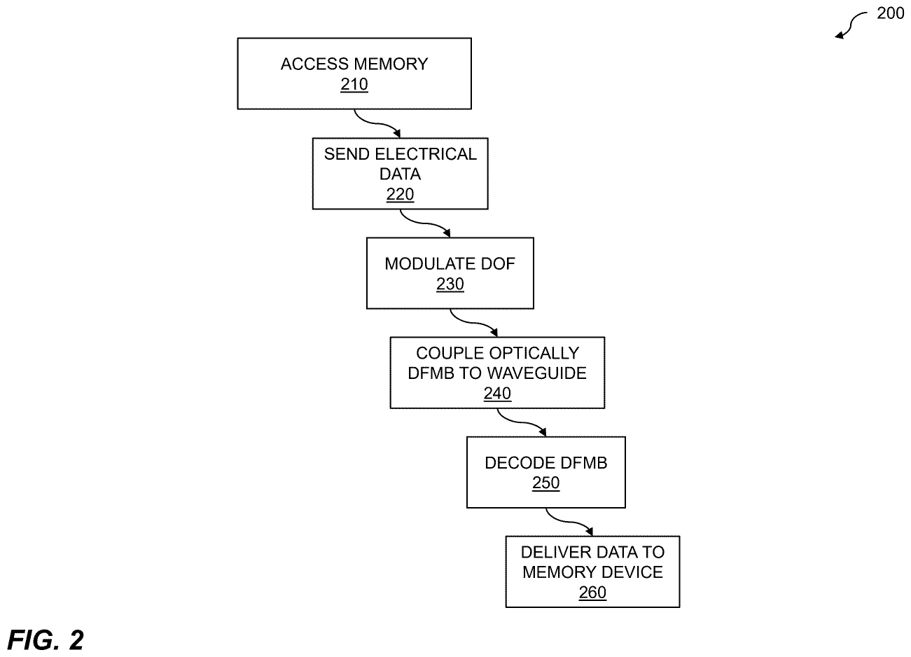

FIG. 2 is a flow diagram for delivering data to a memory device. Circuits such as processors access memory in order to load (e.g., read) and store (e.g., write) data. The processors perform operations on and with the data to perform computations, and to execute algorithms and heuristics, among other operations. The data is provided to the processors by loading the data from memory devices, and results of processing the data can be stored in the memory devices. Latency associated with memory access operations, whether loading data or storing data, is critical to processing performance. If data cannot be provided to a processor in time, a processor can stall, resulting in processing delays. If data generated by the processor cannot be stored in time, the processor can again be delayed while the data is stored, or the data can be lost. Thus, delivering data to a memory device is critical to processing performance. The memory device can include a memory device within a disaggregated memory structure. Transmitting or delivering data to a memory device within a disaggregated memory structure is enabled by a directly modulated photonic wafer-scale interposer. Circuits, memory devices, and surface-emitting light sources, which can be vertical-cavity surface-emitting lasers (VCSELs), are bonded to a photonic wafer-scale interposer (PWSI). The PWSI includes waveguides for transmitting data. One or more memory devices are grouped by a memory fabric. The grouping results in a disaggregated memory structure. A first circuit accesses memory. The accessing is based on the disaggregated memory structure. Additional circuits can be coupled to the disaggregated memory structure. The first circuit and the additional circuits can share the disaggregated memory structure.

The flow 200 includes accessing memory 210. The accessing memory can include accessing memory by a first circuit within a plurality of circuits. The first circuit can include a chiplet, a core, an SOC, an ASIC, and so on. The first circuit can be bonded to a front side of a photonic wafer-scale interposer (PWSI). The PWSI to which the first circuit is bonded can be the same PWSI to which the memory device to be accessed is bonded. The flow 200 includes sending electrical data 220. Recall that the plurality surface-emitting light sources can comprise a plurality of VCSELs. In embodiments, the accessing includes sending electrical data, by the first circuit, to a first surface-emitting light source within the plurality of surface-emitting light sources. In embodiments, the plurality of surface-emitting light sources comprises a plurality of vertical-cavity surface-emitting lasers (VCSELs). The sending can be accomplished using any means to communicate between circuits. For example, the sending can be based on routes (e.g., wire, interconnect, etc.) on a printed circuit board, a bus interface, a wireless communication protocol such as Bluetooth™, metal layers on a wafer or wafer interposer, and so on. The routes can include metal layers on the PWSI. The electrical data can comprise serialized data, data packets, handshaking signals, etc. A VCSEL can be a semiconductor laser fabricated on a chip. The fabrication can be based on gallium arsenide or another suitable material. The VCSEL can emit light in a perpendicular direction to the chip. The direction can be up (e.g., away from the chip) or down (e.g., into the chip). When light is emitted down, a window can be provided so that the light can escape through the back of the chip. To aid projection of the light, the substrate of the chip can be thinned. The light that is emitted can be coherent light that is in a wavelength range, such as 850 nm - 950 nm. Other ranges are possible.

The flow 200 includes modulating a degree of freedom (DoF) 230 of light. Embodiments include modulating a degree of freedom (DoF) of a light beam emitted by the first surface-emitting light source, wherein the emitted light beam comprises a degree of freedom modulated beam (DFMB), wherein the DFMB is based on the electrical data that was sent. The modulating can be based on current injection into the first surface-emitting light source, which can be a first VCSEL. The current injection can include asymmetric current injection, adjusted current, and so on. The degree of freedom modulation can comprise intensity modulation. The injected current can be used modulate the intensity of the light emitted by the VCSEL. The intensity of the light can be varied once sufficient current has been injected to enable the VCSEL to lase. In a usage example, a first amount of injected current produces a first light intensity that can represent a logic zero, and a second amount of injected current produces a second light intensity that can represent a logic one. The first amount of injected current can be 0 mA. The degree of freedom modulation can comprise polarization modulation. In a usage example, the light emitted by the VCSEL can include an s-polarization, which includes polarization that is normal or perpendicular to a surface of incidence, or a p-polarization, which includes polarization that is parallel to a surface of incidence. The degree of freedom modulation can comprise mode modulation. A mode can include a transverse electromagnetic (TEM) mode. In a usage example, the TEM modes can include TEM₀₀, TEM₁₀, and TEM₀₁. The TEM₀₀ mode can include a fundamental mode, while the TEM₁₀ mode and the TEM₀₁ mode can include higher order modes. The degree of freedom modulation can comprise a wavelength of the first VCSEL. In a usage example, the wavelength modulation is based on a VCSEL chirp. The VCSEL chirp can be induced by the current injection.

The flow 200 includes coupling optically the DFMB to a waveguide 240. Embodiments include coupling optically the DFMB to a waveguide with the plurality of waveguides, wherein the waveguide is further coupled to an optical decoding element. The coupling optically can be accomplished using an optical coupler. The optical coupler couples the DFMB to an optical medium, such as a waveguide within the PWSI. The optical medium can comprise an optical fiber, a multicore fiber, and so on. The optical coupler can be based on a variety of optical elements, techniques, and so on. In a usage example, the coupling optically is accomplished by a grating coupler. The grating coupler can include a periodic grating that can transfer the DFMB with low loss into the optical medium. The coupling optically can be accomplished by a mirror. In a usage example, the mirror can include a nano-imprint lithography mirror. The DFMB that was emitted by the surface-emitting light source, which can be a VCSEL, can be angled. The angling can be based on a micro-optical element (MOE). The angling the DFMB can be used to complement an angle associated with the coupling of the DFMB to the waveguide. The optical decoding element can be based on a variety of optical elements, optical techniques, and so on. The optical decoding element can separate different degrees of freedom of light from the DFMB. The separated degrees of freedom of light can be decoded into electrical data that was sent as electrical data from the first circuit.

The flow 200 includes decoding the DFMB 250. Embodiments include decoding, by the optical decoding element, the DFMB into the electrical data that was sent. The optical decoding element can accomplish decoding the DFMB based on a variety of decoding techniques. In a usage example, the optical decoding element comprises a grating coupler. The grating coupler can separate different degrees of freedom of light from each other. In a usage example, the separated degrees of freedom of light can be sent to optical receivers, where the optical receivers can convert the optical data to electrical data. In another usage example, the grating coupler can indicate when a first degree of freedom is active in the optical medium, which can comprise a logic “1.” The absence of the signal from the grating coupler can comprise a logic “0.” Clocking, such as clock and data recovery (CDR) circuits, can synchronize the DFMB with the receiving and/or decoding circuits. The optical decoding element can comprise a polarization filter. The polarization filter can enable a first polarization of light to pass through the polarization filter while a second polarization of light is reflected by the polarization filter. In further embodiments, the optical decoding element comprises a polarization multiplexor (PMUX). The polarization multiplexer can separate the different polarizations of the DFMB at the far end of the waveguide.

The flow 200 includes delivering the data to a memory device 260. Embodiments include delivering the electrical data that was decoded to a memory device within the disaggregated memory structure. The electrical data can be delivered to the memory device using a variety of techniques. The delivery techniques can be based on using wire, interconnect, metal layers, and so on. The metal layers can include metal layers within a circuit board, a wafer, an interposer, and so on. As discussed earlier, the interposer can include a photonic wafer-scale interposer. In a usage example, the delivering data is accomplished using metal layers on or within the PWSI. The metal layers, which enable interconnection between and among circuits, chiplets, and other elements, can be fabricated on or within a circuit board, wafer, or interposer. As was the case for sending the data from the first circuit to the first surface-emitting light source, using the metal layers can offer significant inter-chiplet communications speed due to short wire lengths, and reduced “parasitics” such as resistance, capacitance, and inductance. The data that was delivered can comprise a memory request or another memory related communication. The memory device can send data in response to the request via similar steps using another waveguide within the PWSI. In this way, low-latency memory access can be enabled on a directly modulated PWSI with one or more disaggregated memories.

Various steps in the flow 200 may be changed in order, repeated, omitted, or the like without departing from the disclosed concepts. Various embodiments of the flow 200, or portions thereof, can be included in an apparatus for transmitting data or system that is configured to transmit data.

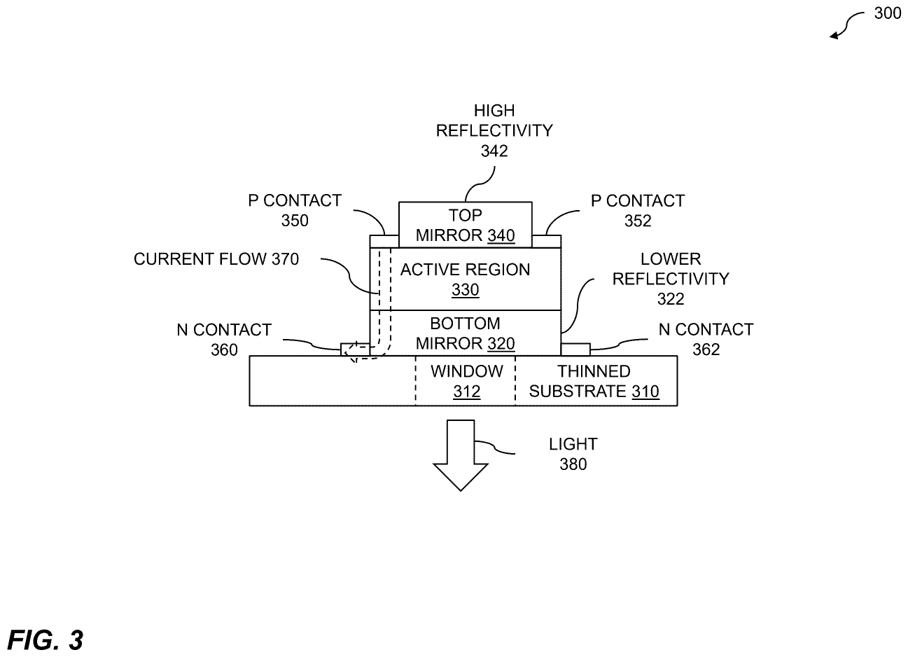

FIG. 3 is a cross-section of a VCSEL. The VCSEL can be used to transmit data between system elements such as circuits, memory devices, and so on. A VCSEL can enable disaggregated memory structures on a directly modulated photonic wafer-scale interposer. Circuits, memory devices, and vertical-cavity surface-emitting lasers (VCSELs) can be bonded to a photonic wafer-scale interposer (PWSI). The PWSI includes waveguides that can be used to communicate among the circuits, the memory devices, and the VCSELs. One or more memory devices are grouped by a memory fabric. The grouping results in a disaggregated memory structure, where the memory devices are not tightly bound to processors. A first circuit accesses memory. The accessing is based on the disaggregated memory structure. Additional circuits can be coupled to the disaggregated memory structure. The first circuit and the additional circuits share the disaggregated memory structure.

The block diagram 300 includes a thinned substrate 310. The thinned substrate can include a variety of materials suitable to fabricating a VCSEL. In a usage example, the substrate can include a gallium-arsenide (GaAs) substrate. Other materials that can be used for the substrate can include aluminum-gallium-arsenide (AlGaAs), germanium (Ge), sapphire, and so on. The substrate can be thinned to enable fabrication of an aperture or window 312. The thinning of the substrate can be accomplished by grinding, polishing, etching, and so on. Light in the form of a polarization-modulated beam (PMB) is emitted by the VCSEL. The light emitted by the VCSEL can exit the VCSEL by passing through the window in the thinned substrate.

The VCSEL structure comprises an active region that is placed between two highly reflective mirrors. The first mirror includes a first reflectivity, and the second mirror includes a second reflectivity. In a usage example, the two highly reflective mirrors can be based on Distributed Bragg Reflectors (BDRs). These mirrors can be formed from multiple, alternating layers of materials, where the materials have different refractive indices. The block diagram 300 includes a bottom mirror 320. The bottom mirror can comprise an n-Distributed Bragg Reflector. The bottom mirror can include a reflectivity that is lower than a top mirror (described below). In a usage example, the lower reflectivity 322 of the bottom mirror can include a reflectivity of 93 percent to 99 percent, or another suitable reflectivity. The n-Distributed Bragg Reflectors associated with the bottom mirror can be insulated from other layers in the block diagram by an oxide layer (not shown).

The block diagram 300 includes an active region 330. The active region can comprise a region in which light that is emitted by the VCSEL can be generated. The light can be generated using a variety of techniques. In a usage example, the active region can include a structure such as a quantum well structure. The active region can be located within a laser cavity. The block diagram 300 can include an additional oxide layer (not shown) between the active region and a top DBR mirror. The oxide layer between the bottom mirror and the active area, and the oxide layer between the active layer and the top mirror may or may not be present in the VCSEL. When present, the oxide layers can confine the light and electrical current within the active area. The block diagram 300 includes a top mirror 340. The top mirror can comprise a p-Distributed Bragg Reflector mirror. The top mirror can include a high reflectivity 342. In a usage example, the reflectivity of the top DBR can include a reflectivity of 99.4 percent to 99.9 percent. Other suitable reflectivities can be implemented.

An electrical current is applied to the VCSEL in order for the VCSEL to lase and to emit coherent light. The applied electrical current can include a DC current, a pulsed current, and so on. The current can include a symmetrical current, an asymmetrical current, etc. The applied current can modulate the light emitted by the VCSEL. In embodiments, modulating is based on asymmetric current injection. An injected asymmetrical current can include a current that is unbalanced or unequal with respect to distribution and/or direction. In a usage example, the current is asymmetrical about the x-axis, that is, the asymmetrical current has a DC offset. The injection of the asymmetrical current can cause the modulated light emitted by the VCSEL to include a polarization. Changing the injected asymmetrical current can change the polarization of the emitted light. The VCSEL can include a ferroelectric liquid crystal layer (FLC). The FLC can include liquid crystals that can be oriented by an electric field. Applying a voltage to the FLC can influence the polarization of light emitted by the VCSEL. In a usage example, a VCSEL with an FLC can include a bottom DBR, and a middle DBR with the FLC layer on top of the middle layer. A top DBR can be included on top of the FLC layer. Other layouts are possible.

Electrical current can be applied to the top p-contact. The p-contact can include a single contact, a ring contact, a “broken ring” contact where the ring is broken into two or more segments, and so on. In the block diagram 300, the contact includes one or more p-contacts such as p-contact 350 and p-contact 352. The electrical current can exit the bottom of the VCSEL via one or more n-contacts. The n-contacts can include a single contact, a ring contact, a broken ring contact, etc. In the block diagram 300, the one or more n-contacts include n-contact 360 and n-contact 362. In a usage example, a p-contact ring and an n-contact ring can be concentric broken rings. By accessing a portion of the p-contact ring and the opposite (e.g., diagonally opposite) n-contact ring, a first polarization can be achieved. By accessing the previously unused portion of the p-contact and the previously unused portion of the n-contact, a second polarization can be achieved. In these cases, the electrical current flows 370 from a first p-contact to a second n-contact (e.g., diagonal opposites), from a second p-contact to a first n-contact, and so on. The VCSEL emits light 380. The light from the VCSEL can be emitted at an angle that can be substantially normal to a substrate, chip, PCB, interposer, etc. to which the VCSEL can be coupled. When there is a purpose for the light emitted by the VCSEL to be angled, then an optical device can be used. The purpose for angling the light can include enhancing optical coupling of the polarization-modulated beam (PMB). Embodiments include angling the PMB that was emitted by the VCSEL, wherein the angling is based on a micro-optical element (MOE). The MOE can include a micro lens, a diffractive optical element, a Fresnel lens, an asymmetric non-focusing optical device, and so on.

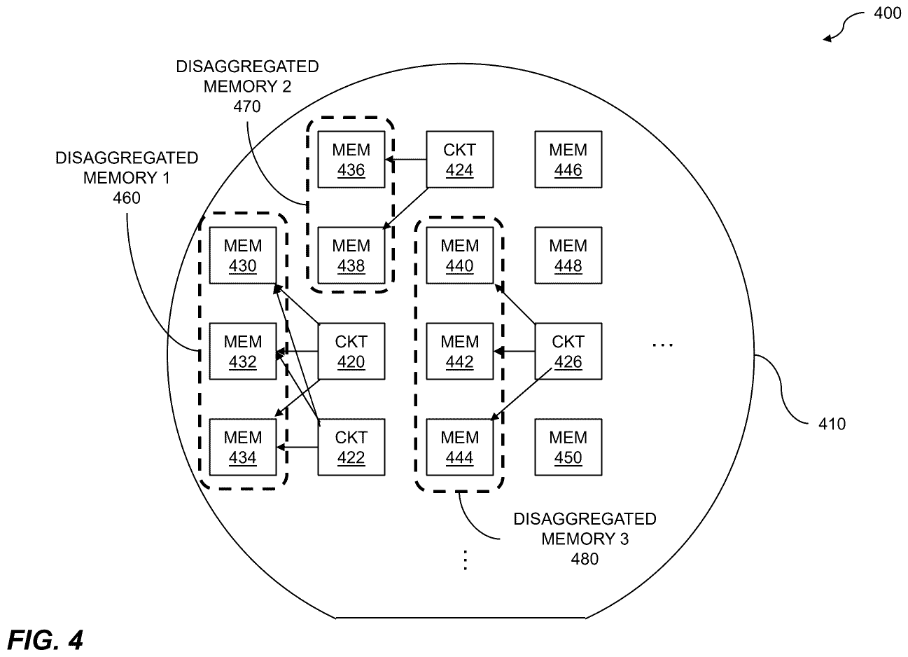

FIG. 4 is an architectural example of a disaggregated memory structure on a photonic wafer-scale interposer. Described previously and throughout, disaggregated memory structures on a directly modulated photonic wafer-scale interposer enable transmitting data. The data can be transmitted between circuits and memory devices within a disaggregated memory structure. Circuits, memory devices, and surface-emitting light sources, which can be vertical-cavity surface-emitting lasers (VCSELs), are bonded to a front side of a photonic wafer-scale interposer (PWSI). The PSWI includes waveguides for communication among the circuits and the memory devices. A memory fabric groups one or more memory devices. The grouping results in a disaggregated memory structure. A first circuit accesses memory. The accessing is based on the disaggregated memory structure.

A disaggregated memory structure, as shown on a PWSI in architectural example 400, differs from a traditional memory structure in which each chip such as a processor chip can be tightly coupled to memory device. The disaggregated memory structure gathers memory devices together into a group. One or more memory devices within the group can be allocated to a given processor chip. Data can then be transmitted between the one or more memory devices and the processor chip. When the processor chip has completed a task, for example, the one or more memory devices that were allocated can be allocated to other processor chips.

The architectural example 400 includes a wafer 410. The wafer can comprise a silicon wafer, a glass wafer, and so on. The wafer can comprise a wafer-scale interposer. In the example, the wafer-scale interposer comprises a photonic wafer-scale interposer (PWSI). In embodiments, a plurality of circuits and a plurality of memory devices are bonded to a front side of the PWSI. The circuits can include circuit 420, circuit 422, circuit 424, circuit 426, and so on. Any number of circuits can be bonded to the front side of the PWSI. The memory devices can include memory 430, memory 432, memory 434, memory 436, and memory 438. The memory devices can further include memory 440, memory 442, memory 444, memory 446, memory 448, and memory 450. The PWSI can include any number of memory devices.

Embodiments include grouping, by a memory fabric, one or more memory devices within the plurality of memory devices, wherein the grouping results in a disaggregated memory structure. A memory fabric can include a memory organization that includes high performance interconnection with low access latency. The interconnection enables connections between and among high-performance memory devices and circuits such as processors, AI accelerators, SoCs, and so on. The memory fabric can enable a unified and accessible grouping of memory resources. The memory fabric can be based on a variety of communication techniques. In embodiments, the memory fabric is based on data packets. A data packet can include a header, a payload, and a trailer. The data packet can include a source, a destination, data, checksums, etc. In other embodiments, the memory fabric is based on a High Bandwidth Memory interface. The High Bandwidth Memory (HBM) interface enables communications between high bandwidth memories, circuits such as processors, and the like. In further embodiments, the memory fabric is based on a Compute Express Link (CXL) interface. The CXL interface can enable circuits such as processors to access and to share memory resources such as memory devices with other processors, special purpose processors, ASICs, SOCs, etc. In embodiments, the CXL interface includes memory pooling. Memory pooling can enable a plurality of processors to share a plurality of memory resources.

The result of the memory device grouping can be one or more disaggregated memory structures. Three disaggregated memory structures are shown. Disaggregated memory 1 460 comprises memory 430, memory 432, and memory 434. Disaggregated memory 2 470 comprises memory 436 and memory 438. Disaggregated memory 3 480 comprises memory 440, memory 442, and memory 444. While three disaggregated memory structures are shown, other numbers of disaggregated memory structures can be formed based on grouping one or more memory devices.

Circuits can access memory devices within the disaggregated memory structures. Circuit 420 and circuit 422 can access memories 430, 432, and 444 within disaggregated memory 1. Circuit 424 can access memories 436 and 438 within disaggregated memory 2. Circuit 426 can access memories 440, 442, and 444 within disaggregated memory 3. One or more of the memory devices within each disaggregated memory structure can be accessible by each of the circuits associated with the disaggregated memory structure. The access by each circuit to a given memory device can include exclusive access such as access for a period of time or a number of cycles, simultaneous access, etc. In a usage example, simultaneous access of memory 432 by circuit 420 and circuit 422 can enable data transfer between circuit 420 and 422.

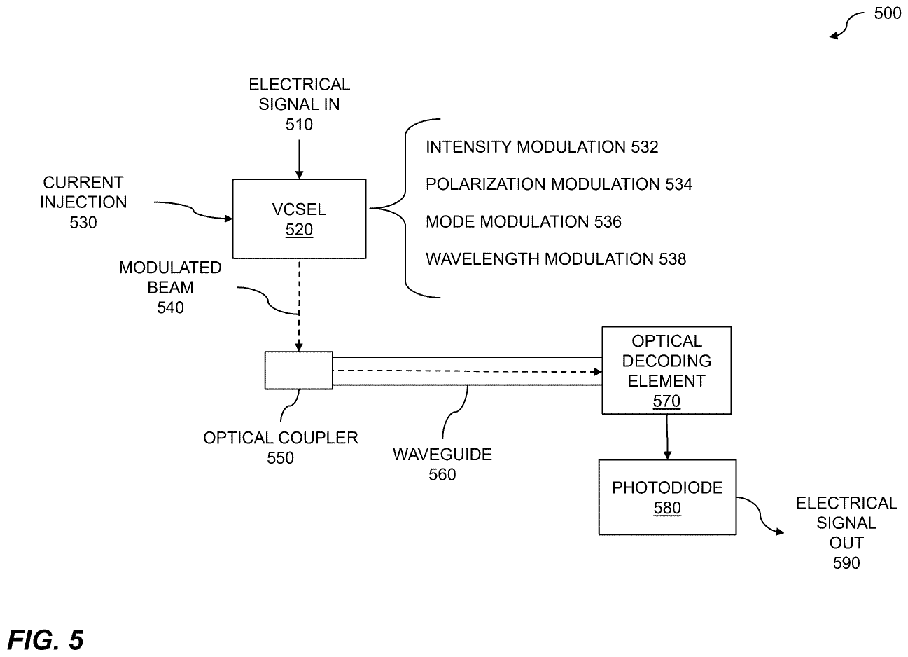

FIG. 5 is a block diagram of an optical link with VCSEL modulation. A degree of freedom optical link enables transmitting data among circuits and memory devices in a disaggregated memory. The disaggregated memory can be established within a directly modulated photonic wafer-scale interposer (PWSI). In a usage example, a first circuit can include a processor, and a second circuit can include a highspeed memory such as a high bandwidth memory (HBM). The optical link reduces memory access latency, thereby providing the first circuit with data as the data is required. The data is provided in time to prevent the first circuit from stalling due to data starvation. A plurality of circuits, memory devices, and surface-emitting light sources, which can be vertical-cavity surface-emitting lasers (VCSELs), are bonded to a photonic wafer-scale interposer (PWSI). The PWSI includes waveguides. Memory devices are grouped by a memory fabric. The grouping results in a disaggregated memory structure. A first circuit accesses memory. The memory access is based on the disaggregated memory structure. The optical link with VCSEL modulation is enabled by disaggregated memory structures on a directly modulated photonic wafer-scale interposer.

The block diagram 500 includes an electrical signal in 510. The electrical signal can represent data such as image data, video data, and audio data; artificial intelligence (AI) weights, biases, and data; and so on. The electrical signal can represent parallel data such as a dataset with bytes, words, etc. The electrical data can represent serial data. In embodiments, the plurality of surface-emitting light sources comprises a plurality of vertical-cavity surface-emitting lasers (VCSELs). The surface-emitting light sources can include LEDs, laser diodes, and so on. In the block diagram, the electrical signal is provided to a VCSEL 520. A light beam emitted by the VCSEL can be modulated. The modulating of the light beam is based on degree of freedom (DoF) modulation. The emitted light beam comprises a degree of freedom modulated beam (DFMB). The DFMB is based on the electrical data that was sent.

The block diagram 500 includes current injection 530. The current injection can include asymmetric current injection, adjusted current, and so on. The current injection can comprise the basis for modulating a degree of freedom of a surface-emitting light source such as a vertical-cavity surface-emitting laser (VCSEL). In the block diagram 500, the degree of freedom modulation includes intensity modulation 532. The injected current can be used modulate the intensity of the light emitted by the VCSEL. The intensity of the light can be varied once sufficient current has been injected to enable the VCSEL to lase. In a usage example, a first amount of injected current produces a first light intensity that can represent a logic zero, and a second amount of injected current produces a second light intensity that can represent a logic one. The first amount of injected current can be zero. In the block diagram 500, the degree of freedom modulation includes polarization modulation 534. In a usage example, the light emitted by the VCSEL can include an s-polarization, which includes polarization that is normal or perpendicular to a surface of incidence, or a p-polarization, which includes polarization that is parallel to a surface of incidence. In the block diagram 500, the degree of freedom modulation includes mode modulation 536. A mode can include a transverse electromagnetic (TEM) mode. In a usage example, the TEM modes can include TEM₀₀, TEM₁₀, and TEM₀₁. The TEM₀₀ mode can include a fundamental mode, while the TEM₁₀ mode and the TEM₀₁ mode can include higher order modes. In the block diagram 500, the degree of freedom modulation includes a wavelength 538 of the first VCSEL. In a usage example, the wavelength modulation is based on a VCSEL chirp.

In the block diagram 500, the modulating includes emitting, by the VCSEL, a degree of freedom modulated beam (DFMB) 540, wherein the DFMB is based on the electrical data that was sent. The DFMB can be directed toward an optical coupler 550. The optical coupler can include a coupler on or within a circuit board, a wafer, an interposer, etc. In a usage example, the optical coupler can be on or within the PWSI. The optical coupler couples the DFMB to an optical medium. The optical medium can comprise a waveguide. The waveguide can be a waveguide within the plurality of waveguides included in the PWSI. The optical medium can comprise a fiber, a multicore fiber, and so on. The fiber can connect to circuits, chips, switches, accelerators, memory devices, etc. external to the PWSI. The optical coupler can be based on a variety of optical elements, techniques, and so on. In a usage example, the coupling optically is accomplished by a grating coupler. The grating coupler can include a periodic grating that can transfer the DFMB with low loss into the optical medium. In another example, the coupling optically is accomplished by a mirror. In a further example, the mirror can include a nano-imprint lithography mirror. The DFMB that was emitted by the VCSEL can be angled. The angling can be based on a micro-optical element (MOE) (not shown). The angling the DFMB can be used to complement an angle associated with the coupling the DFMB to the waveguide.

The block diagram 500 includes a waveguide 560. The waveguide can include an optical medium that is capable of transferring the DFMB coupled to the waveguide by the optical coupler. The waveguide can include a waveguide on or within a wafer, an interposer such as the PWSI, and so on. As described above, the waveguide can be replaced by an optical fiber, a multicore fiber, and so on. The block diagram 500 includes an optical decoding element (ODE) 570 to which the waveguide is further coupled. The ODE can be based on a variety of optical elements, optical techniques, and so on. The ODE can separate different degrees of freedom of light from the DFMB. The separated degrees of freedom of light (e.g., optical data) can be decoded into electrical data that was sent as the electrical signal input. The ODE can accomplish decoding the DFMB based on a variety of decoding techniques. The ODE can comprise a grating coupler. The grating coupler can separate different degrees of freedom of light from each other. In a usage example, the separated degrees of freedom of light can be sent to optical receivers, where the optical receivers can convert the optical data to electrical data. In another usage example, the grating coupler can indicate when a first degree of freedom is active in the optical medium, which can comprise a logic “1.” The absence of the signal from the grating coupler can comprise a logic “0.” Clocking, such as clock and data recovery (CDR) circuits, can synchronize the DFMB with the receiving and/or decoding circuits. The optical decoding element can comprise a polarization filter. The polarization filter can enable a first polarization of light to pass through the polarization filter while a second polarization of light is reflected by the polarization filter. The optical decoding element can comprise a polarization multiplexor (PMUX). The multiplexer can combine different polarizations when the DFMB is coupled optically to the waveguide, and the multiplexer can separate the different polarizations of the DFMB at the far end of the waveguide.

Some examples can include transforming each optical signal within at least two optical degrees of freedom signals, by a unique photodiode, to an electrical signal. The transforming each optical signal can result in at least two electrical signals. The block diagram 500 includes a photodiode 580. More than one photodiode can be included, where each photodiode can transform or decode an optical signal into an electrical signal. In the block diagram 500, the ODE decodes the DFMB into the electrical data that was sent. The decoded DFMB is sent as an electrical signal out 590. The at least two electrical signals can be assembled into a single electrical signal, where the single electrical signal comprises the electrical data that was sent. The single electrical signal that includes the electrical data that was sent can be sent to a destination element such as a second circuit. The destination element can include a processor, an AI accelerator chiplet, a switching chiplet, a disaggregated memory, etc.

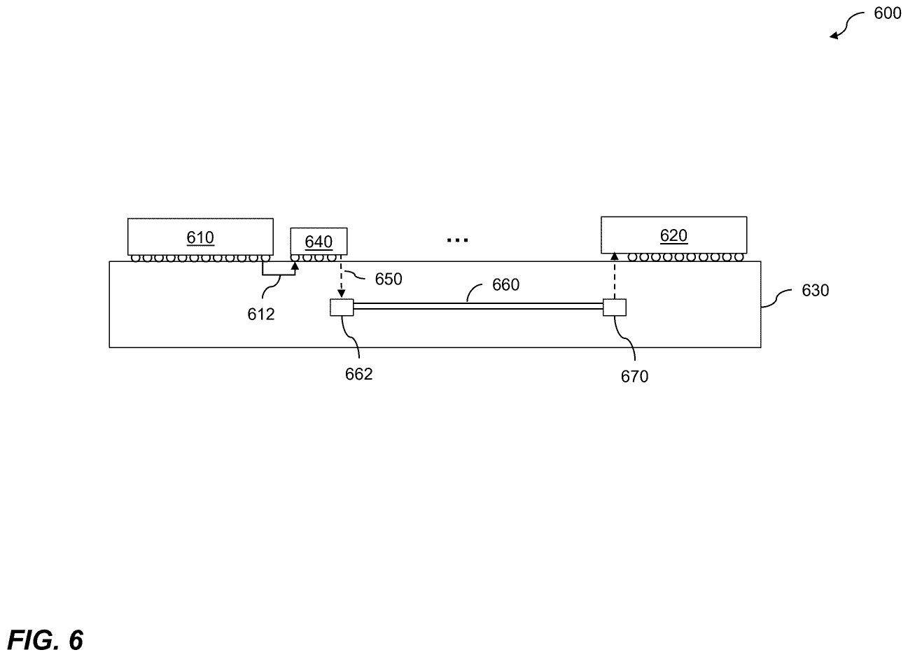

FIG. 6 is an apparatus for disaggregated memory structures on a photonic wafer-scale interposer. The disaggregated memory structures can be accessible to circuits such as processors via an optical link. The optical link can include a waveguide within a photonic wafer-scale interposer (PWSI). The optical link can be established to enable transmitting data between circuits and memory devices. The memory devices can be included within the disaggregated memory structures. The optical link can be used to send data from a first circuit to a second circuit. The circuits and memory devices can be co-located on a circuit board, wafer, or interposer such as a photonic wafer-scale interposer (PWSI); located in different multiprocessors; located in different datacenters; and so on. A plurality of circuits, memory devices, and surface-emitting light sources are bonded to a photonic wafer-scale interposer (PWSI). In embodiments, the plurality of surface-emitting light sources comprises a plurality of vertical-cavity surface-emitting lasers (VCSELs). The PWSI includes waveguides that can be used for transmitting data. Memory devices are grouped by a memory fabric. The grouping results in a disaggregated memory structure. A first circuit accesses memory. The accessing is based on the disaggregated memory structure. The apparatus enables transmitting data using disaggregated memory structures on a directly modulated photonic wafer-scale interposer.

An apparatus is disclosed for transmitting data comprising: a plurality of circuits; a plurality of memory devices; a plurality of surface-emitting light sources; a photonic wafer-scale interposer (PWSI), wherein the PWSI includes a plurality of waveguides and wherein the plurality of circuits, the plurality of memory devices, and the plurality of surface-emitting light sources are bonded to a front side of the PWSI; and a memory fabric, wherein the memory fabric groups one or more memory devices within the plurality of memory devices, wherein the grouping results in a disaggregated memory structure.

The apparatus 600 includes a plurality of circuits. The plurality of circuits can include a first circuit 610 within the plurality of circuits. Noted previously and throughout, the circuits can include one or more of chips, chiplets, cores, cores on a wafer, SoCs, processors, AI accelerators, switches, and so on. The apparatus 600 includes a plurality of memory devices such as memory device 620. The memory devices can include high speed memory devices. In a usage example, the memory devices include high bandwidth memory (HBM) devices. Other high speed memory devices can also be used. The memory device can be part of a disaggregated memory.

The apparatus 600 includes a photonic wafer-scale interposer (PWSI) 630, wherein the PWSI includes a plurality of waveguides and wherein the plurality of circuits, the plurality of memory devices, and the plurality of surface-emitting light sources are bonded to a front side of the PWSI. The PWSI can comprise a wafer, where the wafer includes a material suitable for fabricating the PWSI. In a usage example, the PWSI comprises a silicon wafer or a glass wafer. The plurality of surface-emitting light sources can include a plurality of LEDs, laser diodes, VCSELs, and so on. A VCSEL 640 can be included in the apparatus 600. The VCSEL 640 can comprise a single VCSEL, an array of VCSELs, etc. The VCSEL can comprise a suitable fabrication material such as gallium-arsenide. The waveguides can be used to transmit data between the first circuit and the memory device (which can be a second circuit). The transmitting can be accomplished by using the VCSEL to convert electrical data to optical (e.g., light based) data.

The apparatus 600 includes a memory fabric, wherein the memory fabric groups one or more memory devices within the plurality of memory devices, wherein the grouping results in a disaggregated memory structure. The memory device 620 can comprise a memory device within the disaggregated memory structure. In contrast to traditional memory structures where a memory device can be tightly coupled to a processor, in a disaggregated memory structure, the memory devices are shared among processors. In a usage example, a processor requires access to memory to obtain data for a computation. The one or more memory devices within the disaggregated structure are made accessible to the processor to provide needed data to the processor. When the one or more memory devices are no longer required by the processor, the memory devices can be “released” and reassigned to other processors as needed. Thus, the disaggregated memory structure can flexibly assign memory devices to processors as needed. The disaggregated memory structure can assign additional memory devices (expand) and free additional memory devices (contract) while a processor is executing.

The first circuit sends electrical data to the VCSEL. The sending can be accomplished using wire 612 or another interconnect associated with the PWSI. The VCSEL, when modulated, emits a degree of freedom modulated beam (DFMB) 650. The modulating can be based on current. The current can be injected, altered, and so on. In a usage example, the modulating is based on asymmetric current injection. The asymmetry of the current can be relative to an x-axis (e.g., can include a DC offset), based on a forward current and a reverse current, related to a pulse train, etc. In a usage example, the current injection can be used to control a polarization of the light emitted by the VCSEL. The modulating can comprise altering current to the VCSEL. The altering the current can include increasing and decreasing the current, reversing the current, applying and removing the current, etc. In a usage example, the altering the current can control a mode such as a TEM mode of light emitted by the VCSEL. The modulating can comprise injecting current into the VCSEL. The injecting the current can change carrier density with an active region of the VCSEL. In a usage example, the injecting current can control a wavelength of light emitted by the VCSEL.

Noted above, the first circuit 610 can send data to a memory device using the VCSEL and additional optical elements. The circuits, VCSELS, and memory devices can be connected, attached, bonded, or otherwise coupled to a circuit board, a wafer, an interposer, and so on. The interposer can comprise a directly modulated photonic wafer-scale interposer (PWSI), wherein the PWSI includes a plurality of waveguides. While one circuit, one memory device, and one VCSEL are shown, the apparatus can include any number of circuits, devices, and VCSELs.

The circuits can include AI accelerator chiplets, switching chiplets, ASICs, I/O chiplets, and so on. In embodiments, the PWSI comprises an optical wafer-scale AI accelerator, wherein one or more chiplets within the plurality of chiplets comprise one or more artificial intelligence (AI) accelerators. The AI accelerator can be used for machine learning (ML), natural language processing (NLP), and the like. In other embodiments, the PWSI comprises an optical wafer-scale network switch, wherein one or more chiplets within the plurality of chiplets comprise one or more switching chiplets. The network switch can be used to provide data to compute-intensive applications such as AI, ML, image processing, etc.

The DFMB 650 emitted by the VCSEL can be conveyed to an optical coupler. The apparatus 600 can include an optical coupler 662, wherein the optical coupler couples optically the DFMB to a first waveguide 660 within the plurality of waveguides. An optical medium, such as the first waveguide, can include a low loss optical medium appropriate for sending the DFMB. In addition to a waveguide, the optical medium can also include an optical fiber. In a usage example, the optical medium can include a degree of freedom maintaining fiber. The coupling optically can be based on a grating coupler. The grating coupler can include a periodic grating that can transfer the DFMB with low loss into the waveguide. The coupling optically can be based on a bent waveguide. The bent waveguide can include a high containment region, where the high containment region minimizes loss from the DFMB. The coupling optically can be based on an off-axis diffractive lens. The off-axis diffractive lens can be based on surfaces comprising different thicknesses or heights that diffract light, thereby bending and focusing the light onto an input aperture of a waveguide. The coupling optically can be based on a mirror. In a usage example, the mirror can include a nano-imprint lithography mirror. The DFMB that was emitted by the VCSEL can be angled, where the angling can be based on a micro-optical element (MOE). The angling the DFMB can be used to complement an angle associated with the coupling the DFMB to the optical medium. The angling can also compensate for variations in a wafer or interposer across the surface of the wafer or interposer. In a usage example, the DFMB emitted by the VCSEL can be pre-angled to an angle such as 9.74 degrees, substantially 9.74 degrees, etc., and a mirror such as a crystallographic etched mirror can include an angle such as 54.74 degrees, substantially 54.75 degrees, etc. The combination of pre-angling and angling can enable coupling the DFMB to a waveguide at an angle substantially normal to an entrance aperture of the waveguide.

The micro-optical element (MOE) can be based on one or more optical techniques. The MOE can comprise a micro lens. The micro lens can be coupled to a first surface-emitting light source such as the VCSEL, a laser diode (LD), an LED, and so on. The micro lens can pre-angle the emitted light. The MOE can comprise a diffractive optical element. The diffractive optical element can create a light phase profile that can focus, shape, or split the emitted light. The MOE can comprise a Fresnel lens. The Fresnel lens can use concentric grooves or rings to focus the emitted light. The MOE can comprise an asymmetric non-focusing optical device. The asymmetric non-focusing optical device can enable light to transmit through the device preferentially, where the light can pass through more easily in one direction than another direction. The asymmetric non-focusing optical device can couple light to an optical medium such as a waveguide and can suppress a portion of reflected light back to the surface-emitting light source.

The apparatus 600 can include an optical decoding element (ODE) 670, wherein the optical decoding element is further coupled to the first waveguide, and wherein the optical decoding element decodes the DFMB into the electrical data that was sent. The ODE can separate different degrees of freedom of light from the DFMB. The separated degrees of freedom can be based on light intensity, light polarizations, light modes such as TEM modes, light wavelengths, etc. The separated degrees of freedom of light (e.g., optical data) can be decoded into electrical data that was sent by the first circuit. As described above and throughout, the ODE can accomplish decoding based on a plurality of decoding techniques. In a usage example, the optical decoding element comprises a grating coupler. The grating coupler can separate different polarizations of light. In other usage examples, the optical decoding element comprises a polarization filter. The polarization filter can enable a first light polarization to pass through the filter while reflecting a second light polarization. In further usage examples, the optical decoding element comprises a polarization multiplexor (PMUX). The PMUX can multiplex two or more light polarizations. The electrical data that was decoded can be sent to the first memory device 620. The electrical data can comprise a memory request, or another memory operation. Similar steps can be undertaken to send a response, by the first memory device, back to the first circuit. The response can include a second optical link which can include a second VCSEL, a second waveguide, and so on. The first circuit and the first memory device within the disaggregated memory can be located on a different or a common circuit board, a different or a common wafer, a different or a common rack, and so on. The first circuit and the second circuit can be remotely located with respect to each other. “Remotely located” can include locating the first circuit and the second circuit in separate circuit boards or wafers, separate multiprocessors, separate data racks, separate data centers, and so on. Thus, the disaggregated memory can include many different memory devices in different system locations.

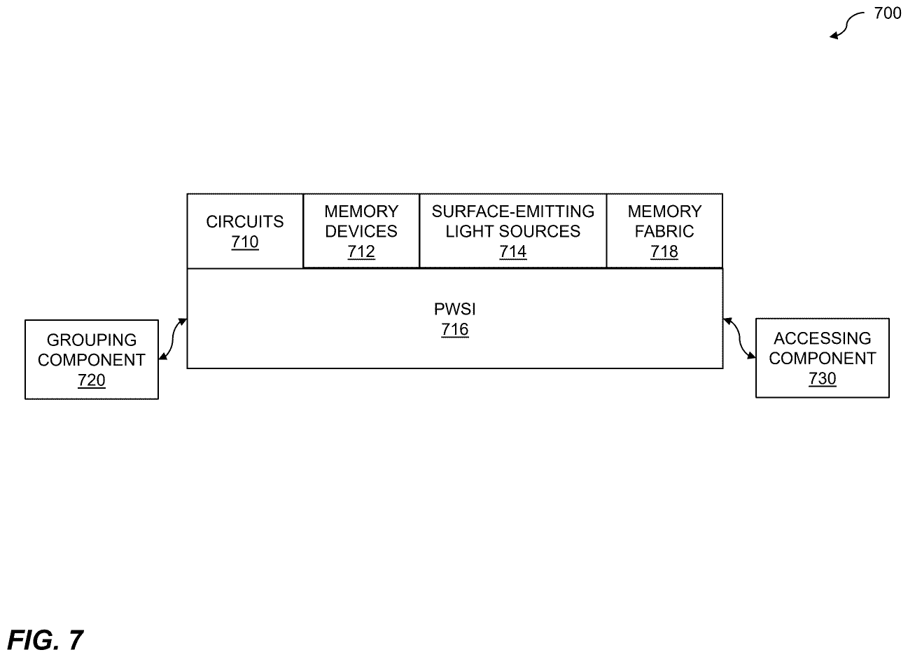

FIG. 7 is a system diagram for disaggregated memory structures on a directly modulated photonic wafer-scale interposer. Circuits, memory devices, and surface-emitting light sources, which can be vertical-cavity surface-emitting lasers (VCSELs), are bonded to a front side of a photonic wafer-scale interposer (PWSI). The PWSI includes waveguides. A memory fabric groups one or more memory devices. The grouping results in a disaggregated memory structure. A first circuit accesses memory. The accessing is based on the disaggregated memory structure. A degree of freedom (DoF) of a light beam can be modulated. The modulated light beam can be emitted by a VCSEL. The emitted light beam comprises a degree of freedom modulated beam (DFMB). The DFMB can be based on the electrical data that was sent. The degree of freedom modulation can include a polarization of light, a light mode, and a light wavelength. The DFMB can be coupled optically to a waveguide or other optical medium such as an optical fiber. The coupling optically can be accomplished using a grating coupler or a mirror. The waveguide can be further coupled to an optical decoding element (ODE). The ODE decodes the DFMB into the electrical data that was sent. The electrical data that was decoded can be delivered to a memory device within the disaggregated memory structure.

Disclosed is a system for transmitting data comprising: a plurality of circuits; a plurality of memory devices; a plurality of surface-emitting light sources; a photonic wafer-scale interposer (PWSI), wherein the PWSI includes a plurality of waveguides, and wherein the plurality of circuits, the plurality of memory devices, and the plurality of surface-emitting light sources are bonded to a front side of the PWSI; and a memory fabric; wherein the system is configured to: group, by the memory fabric, one or more memory devices within the plurality of memory devices, wherein the grouping results in a disaggregated memory structure; and access memory, by a first circuit within the plurality of circuits, wherein the accessing is based on the disaggregated memory structure.

The system 700 includes a plurality of circuits 710. The plurality of circuits can include chiplets within a plurality of chiplets. The chiplets can include processor chiplets, memory chiplets, AI accelerator chiplets, switching chiplets, I/O chiplets, and so on. The circuits and chiplets can include cores, cores within circuits, cores on or within wavers, and the like. The system 700 includes a plurality of memory devices 712. The memory devices can include SRAM devices, DRAM devices, and so on. In a usage example, the memory devices can include memory chips such as DDR or HBM memory chips. The system includes a plurality of surface-emitting light sources 714. As described above and throughout, the plurality of surface-emitting light sources can include a plurality of VCSELS, LEDs, laser diodes, and so on. In embodiments, the plurality of surface-emitting light sources comprises a plurality of vertical-cavity surface-emitting lasers (VCSELs). The system 700 includes a photonic wafer-scale interposer (PWSI) 716, wherein the PWSI includes a plurality of waveguides, and wherein the plurality of circuits, the plurality of memory devices, and the plurality of surface-emitting light sources are bonded to a front side of the PWSI. The PWSI can be based on a wafer such as a silicon (Si) wafer, a glass wafer, and so on.

As described above and throughout, the surface-emitting light sources, which can be VCSELS, can be modulated to emit a degree of freedom modulated beam. The degree of freedom modulated beam (DFMB) can be coupled optically to a waveguide or other optical medium. Various optical elements can be used as an optical coupler to optically couple the DFMB to a waveguide. The coupling optically can be accomplished using an optical coupler. The optical coupler can comprise a grating coupler. The grating coupler can include a periodic grating that can transfer the DFMB with low loss into the waveguide or other optical medium. The optical coupler can comprise a mirror. In a usage example, the mirror can include a nano-imprint lithography mirror. The DFMB that was emitted by a VCSEL can be angled. The angling can be based on a micro-optical element (MOE). The angling the DFMB can be used to complement an angle associated with the coupling the DFMB to the waveguide. The system 700 can include an optical decoding element (ODE) (not shown). The ODE can be further coupled to the far end of the waveguide. The ODE can distinguish between different degrees of freedom of light from the DFMB emitted by the VCSEL. The ODE can separate different degrees of freedom of light. The separated degrees of freedom of light can be decoded into electrical data that was sent by the first circuit. The ODE can accomplish decoding based on a plurality of decoding techniques. As described previously, the ODE can comprise a grating coupler, a polarization filter, a polarization multiplexor (PMUX), and so on.

The system 700 includes a memory fabric 718. The memory fabric can comprise a high-performance, low-latency interconnect architecture. The memory fabric can couple various memory resources, such as the plurality of memory devices, to compute resources, such as the plurality of circuits. The memory fabric can be included on the PWSI. The memory fabric can comprise a chip on the PWSI, be distributed among a plurality of chips, and so on. The interconnect architecture can be coherent. The memory fabric can abstract a physical location of the memory devices, making it appear to the circuits, such as chiplets, that the memory is local. The memory fabric can include a controller which can direct traffic between nodes within the fabric. The memory fabric can implement distributed control of traffic without the need of a separate controller. In embodiments, the memory fabric is based on data packets. Data packets can comprise units of data transmitted across the memory fabric. Packets may contain headers, payloads, error-checking and/or correction fields, and so on. In some embodiments, the memory fabric is based on a High Bandwidth Memory interface. The High Bandwidth Memory (HBM) interface can communicate with HBM memory chips when one or more HBMs are used as memory devices on the PWSI. In other embodiments, the memory fabric is based on a Compute Express Link (CXL) interface. CXL can be a compute protocol enabling high-bandwidth, low-latency interconnect. In further embodiments, the CXL interface include memory pooling. A memory pooling feature within the CXL can enable a flexible, disaggregated memory structure.

The system 700 includes a grouping component 720. The grouping component is configured to group, by the memory fabric, one or more memory devices within the plurality of memory devices, wherein the grouping results in a disaggregated memory structure. A group can include one or more memory devices. A group can include a number of memory devices based on power of two. Embodiments include regrouping, by the memory fabric, the disaggregated memory structure. The regrouping can be based on changing a number of memory devices within a group. In embodiments, the regrouping comprises adding a memory device, within the plurality of memory devices, to the disaggregated memory structure. One or more memory devices can be added to a group to bolster the number of memory devices available to a circuit based on memory access requirements. In other embodiments, the regrouping comprises removing a memory device, within the one or more memory devices that were grouped, to the disaggregated memory structure. Memory devices can be removed from a group if the circuits that are accessing the group have memory access requirements that can be met by fewer memory devices. More than one disaggregated memory structure can be formed. In embodiments, the grouping includes another one or more memory devices within the plurality of memory devices, wherein the grouping results in a second disaggregated memory structure. A second disaggregated memory structure can be formed to provide memory access to additional circuits within the plurality of circuits.

The one or more disaggregated memory structures that can be formed by the fabric can include one or more unused memory devices. In embodiments, a memory device within the one or more memory devices that were grouped comprises a spare memory device. The spare memory device can be swapped in for a memory device that fails. A failing or failed memory device can be detected by one or more techniques. Embodiments include testing each memory device within the disaggregated memory structure. The testing can be performed on system startup, when a memory device is idle, during operation of the system, and so on. The testing can identify failing and failed devices. Failing and failed memory devices can be swapped out. Further embodiments include replacing a failing memory device within the one or more memory devices, wherein the replacing is based on the spare memory device. The replacing a failing device can maintain a number of functioning memory devices without degrading memory access.

The system 700 includes an accessing component 730. The accessing component is configured to access memory, by a first circuit within the plurality of circuits, wherein the accessing is based on the disaggregated memory. The accessing can be accomplished by the first circuit via the directly modulated photonic wafer-scale interposer (PWSI) with the techniques described in disclosed embodiments. The accessing can comprise a memory access or another memory function. A memory device within the disaggregated memory can respond to the memory access with similar techniques.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system” may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transmitting data comprising:
bonding, to a front side of a photonic wafer-scale interposer (PWSI), a plurality of circuits, a plurality of memory devices, and a plurality of surface-emitting lights sources, wherein the PWSI includes a plurality of waveguides;
grouping, by a memory fabric, one or more memory devices within the plurality of memory devices, wherein the grouping results in a disaggregated memory structure; and
accessing memory, by a first circuit within the plurality of circuits, wherein the accessing is based on the disaggregated memory structure.

2. The method of claim 1 further comprising coupling, by the memory fabric, one or more additional circuits within the plurality of circuits to the disaggregated memory structure.

3. The method of claim 1 wherein the accessing includes sending electrical data, by the first circuit, to a first surface-emitting light source within the plurality of surface-emitting light sources.

4. The method of claim 3 further comprising modulating a degree of freedom (DoF) of a light beam emitted by the first surface-emitting light source, wherein the emitted light beam comprises a degree of freedom modulated beam (DFMB), wherein the DFMB is based on the electrical data that was sent.

5. The method of claim 4 further comprising coupling optically the DFMB to a waveguide within the plurality of waveguides, wherein the waveguide is further coupled to an optical decoding element.

6. The method of claim 5 further comprising decoding, by the optical decoding element, the DFMB into the electrical data that was sent.

7. The method of claim 6 further comprising delivering the electrical data that was decoded to a memory device within the disaggregated memory structure.

8. The method of claim 1 wherein the memory fabric is based on data packets.

9. The method of claim 1 wherein the memory fabric is based on a High Bandwidth Memory interface.

10. The method of claim 1 wherein the memory fabric is based on a Compute Express Link (CXL) interface.

11. The method of claim 10 wherein the CXL interface includes memory pooling.

12. The method of claim 1 further comprising regrouping, by the memory fabric, the disaggregated memory structure.

13. The method of claim 12 wherein the regrouping comprises adding a memory device, within the plurality of memory devices, to the disaggregated memory structure.

14. The method of claim 12 wherein the regrouping comprises removing a memory device, within the one or more memory devices that were grouped, to the disaggregated memory structure.

15. The method of claim 1 wherein the grouping includes another one or more memory devices within the plurality of memory devices, wherein the grouping results in a second disaggregated memory structure.

16. The method of claim 15 further comprising coupling, by the memory fabric, one or more other circuits to the second disaggregated memory structure.

17. The method of claim 16 wherein the accessing includes the second disaggregated memory structure.

18. The method of claim 1 wherein at least one memory device within the one or more memory devices comprises a high bandwidth memory (HBM) chip.

19. The method of claim 18 wherein the HBM chip includes one or more stacks of memory dies.

20. The method of claim 1 wherein a memory device within the one or more memory devices that were grouped comprises a spare memory device.

21. The method of claim 20 further comprising testing each memory device within the disaggregated memory structure.

22. The method of claim 21 further comprising replacing a failing memory device within the one or more memory devices, wherein the replacing is based on the spare memory device.

23. The method of claim 1 wherein the plurality of circuits comprises a plurality of chiplets.

24. The method of claim 1 wherein the disaggregated memory structure comprises one or more memory devices within the plurality of memory devices, wherein the one or more memory devices are dynamically allocated between one or more circuits within the PWSI, and wherein the one or more memory devices are independent from the one or more circuits.

25. The method of claim 1 wherein the plurality of surface-emitting light sources comprises a plurality of vertical-cavity surface-emitting lasers (VCSELs).

26. An apparatus for transmitting data comprising:
a plurality of circuits;
a plurality of memory devices;
a plurality of surface-emitting light sources;
a photonic wafer-scale interposer (PWSI), wherein the PWSI includes a plurality of waveguides and wherein the plurality of circuits, the plurality of memory devices, and the plurality of surface-emitting light sources are bonded to a front side of the PWSI; and
a memory fabric, wherein the memory fabric groups one or more memory devices within the plurality of memory devices, wherein the grouping results in a disaggregated memory structure.

27. The apparatus of claim 26 wherein the PWSI comprises an optical wafer-scale AI accelerator, wherein one or more circuits within the plurality of circuits comprise one or more artificial intelligence (AI) accelerators.

28. The apparatus of claim 26 wherein the PWSI comprises an optical wafer-scale network switch, wherein one or more circuits within the plurality of circuits comprise one or more switching chiplets.

29. A system for transmitting data comprising:
a plurality of circuits;
a plurality of memory devices;
a plurality of surface-emitting light sources;
a photonic wafer-scale interposer (PWSI), wherein the PWSI includes a plurality of waveguides, and wherein the plurality of circuits, the plurality of memory devices, and the plurality of surface-emitting light sources are bonded to a front side of the PWSI; and
a memory fabric;
wherein the system is configured to:
group, by the memory fabric, one or more memory devices within the plurality of memory devices, wherein the grouping results in a disaggregated memory structure; and
access memory, by a first circuit within the plurality of circuits, wherein the accessing is based on the disaggregated memory structure.
